(19) United States
(12) Patent Application Publication
(10) Pub. No.: US 2022/0255002 A1
(43) Pub. Date: Aug. 11, 2022

(54) PROCESS FOR PRODUCING INVERTED POLYMER PHOTOVOLTAIC CELLS

(71) Applicant: ENI S.P.A., Roma (IT)

(72) Inventors: Marja VILKMAN, Helsinki (FI); Riccardo PO', Novara (IT); Chiara CARBONERA, Novara (IT)

(21) Appl. No.: 17/626,065

(22) PCT Filed: Jul. 8, 2020
(86) PCT No.: PCT/IB2020/056407

§ 371 Date: Jan. 10, 2022

(30) Foreign Application Priority Data
Jul. 11, 2019 (IT) 102019000011487

(51) Int. Cl. H01L 51/00

(52) U.S. Cl. CPC H01L 51/004; H01L 51/0036; H01L 51/4253; H01L 51/0037; H01L 51/0035; H01L 51/0047

(57) ABSTRACT

A Process for producing an inverted polymer photovoltaic cell (or solar cell) includes the following steps
providing an electron contact layer (cathode);
depositing a cathodic buffer layer onto said electron contact layer;
depositing a photoactive layer comprising at least one photoactive organic polymer and at least one organic electron acceptor compound onto the cathodic buffer layer;
depositing an anodic buffer layer onto the photoactive layer; and
providing a hole contact layer (anode).

The step of depositing the cathodic buffer layer includes the steps of
forming a layer onto the electron contact layer of a composition comprising having at least one zinc oxide and/or titanium dioxide or a precursor thereof, at least one organic solvent and at least one polymer soluble in the organic solvent; and
plasma treating the layer formed onto the electron contact layer so as to form the cathodic buffer layer.

### TECHNICAL FIELD

The present disclosure relates to a process for producing an inverted polymer photovoltaic cells (or solar cells).

More in particular, the present disclosure relates to a process for producing an inverted polymer photovoltaic cell (or solar cell) comprising the following steps: providing an electron contact layer (cathode); depositing a cathodic buffer layer onto said electron contact layer; depositing a photoactive layer comprising at least one photoactive organic polymer and at least one organic electron acceptor compound onto said cathodic buffer layer; depositing an anodic buffer layer onto said photoactive layer; providing a hole contact layer (anode); wherein the step of depositing said cathodic buffer layer comprises: forming a layer onto said electron contact layer of a composition comprising at least one zinc oxide and/or titanium dioxide or a precursor thereof, at least one organic solvent and at least one polymer soluble in said organic solvent; plasma treating said layer formed onto said electron contact layer so as to form the cathodic buffer layer.

Said process allows to obtain an inverted polymer photovoltaic cell (or solar cell) which is endowed with good power conversion efficiency (PCE) and, in particular, which are able to maintain said power conversion efficiency (PCE) stable over time. Said inverted polymer photovoltaic cell (or solar cell) may be advantageously used for the construction of photovoltaic modules (or solar modules), either on a rigid support, or on a flexible support.

The present disclosure also relates to an inverted polymer photovoltaic cell (or solar cell) obtained through the process above disclosed.

### BACKGROUND

Photovoltaic devices (or solar devices) are devices capable of converting the energy of a light radiation into electric energy. At present, most photovoltaic devices (or solar devices) which may be used for practical applications exploit the physicochemical properties of photoactive materials of the inorganic type, in particular high-purity crystalline silicon. As a result of the high production costs of silicon, scientific research has been orienting its efforts towards the development of alternative organic materials having a polymeric structure [the so-called “polymer photovoltaic cells (or solar cells)”]. Unlike high-purity crystalline silicon, in fact, organic polymers are characterized by a relative synthesis facility, a low production cost, a reduced weight of the relative photovoltaic device, in addition to allowing the recycling of said polymer at the end of the life-cycle of the device wherein it is used. The aforementioned advantages make organic photoactive materials very attracting, in spite of the lower efficiencies of organic-based devices as compared to inorganic photovoltaic cells.

The functioning of polymer photovoltaic cells (or solar cells) is based on the combined use of an electron acceptor compound and an electron donor compound. In the state of the art, the most widely-used electron donor and acceptor compounds in photovoltaic cells (or solar cells) are, respectively, π-conjugated polymers and derivatives of fullerenes, in particular PC61BM ([6,6]-phenyl-C₆₁-butyric acid methyl ester) and PC71BM ([6,6]-phenyl-C₇₁-butyric acid methyl ester).

The basic conversion process of light into electric current in a polymer photovoltaic cell (or solar cell) takes place through the following steps:
1. absorption of a photon from the electron donor compound with the formation of an exciton, i.e. an “electron-hole” pair;
2. diffusion of the exciton in a region of the electron donor compound wherein its dissociation may take place;
3. dissociation of the exciton in the two separated charge carriers [electron (−) and hole (+)];
4. transporting of the carriers thus formed to the cathode [electron (−) through the electron acceptor compound] and to the anode (hole (+) through the electron donor compound), with the generation of an electric current in the circuit of the device comprising said polymer photovoltaic cell (or solar cell).

The photoabsorption process with the formation of the exciton and subsequent transfer of the electron to the electron acceptor compound include the excitation of an electron from the HOMO (Highest Occupied Molecular Orbital) to the LUMO (Lowest Unoccupied Molecular Orbital) of the electron donor compound and subsequently the transfer from this to the LUMO of the electron acceptor compound.

As the efficiency of a polymer photovoltaic cell (or solar cell) depends on the number of free electrons which are generated by dissociation of the excitons, one of the structural characteristics of the electron donor compounds which mostly influences said efficiency is the difference in energy existing between the HOMO and LUMO orbitals of the electron donor compound (the so-called band-gap). The wavelength of the photons which the donor electron compound is capable of collecting and effectively converting into electric energy (the so-called “photon harvesting” or “light-harvesting” process) depends, in particular, on this difference. In order to obtain acceptable electric currents, the band-gap between HOMO and LUMO must not be too high, but at the same time, it must not be too low, as an excessively low gap would decrease the voltage obtainable at the electrodes of the device.

The electron donor compound most commonly used in the production of polymer photovoltaic cells (or solar cells) is regioregular poly(3-hexylthiophene) (P3HT): its regioregularity improves the microstructure ordering and crystallinity and thus favours electrical conductivity. Moreover, said poly(3-hexylthiophene) (P3HT) has optimal electronic and optical characteristics (good HOMO and LUMO orbitals values, suitable absorption coefficient), a good solubility in the solvents used for producing the photovoltaic cells (or solar cells) and a reasonable hole mobility. Other examples of polymers that may be profitably used as electron donor compounds are described, for example, in Chocos C. L. et al., “Progress in Polymer Science” (2011), Vol. 36, pg. 1326-1414; Bian L. et al., “Progress in Polymer Science” (2012), Vol. 37(9), pg. 1292-1331; Chen J. et al., “Accounts of Chemical Research” Vol. 42(11), pg. 1709-1718; Boudreault P. T. et al., “Chemistry of Materials” (2011), Vol. 23(3), pg. 456-469.

Another important characteristic in the production of polymer photovoltaic cells (or solar cells) is the mobility of the electrons in the electron acceptor compound and of the electron holes in the electron donor compound, which determines the facility with which the electric charges, once photo-generated, reach the electrodes. Besides being an intrinsic property of the molecules, mobility is also strongly influenced by the morphology of the photoactive layer, that in turn depends on the reciprocal miscibility of the compounds comprised in said photoactive layer and on the solubility of said compounds.

Moreover, the interface between the electrodes and the photoactive layer should present features that facilitate the charge carrier transfer towards the electrodes.

Finally, a further fundamental characteristic is the resistance to thermo-oxidative and photo-oxidative degradation of said compounds, which must be stable under the operating conditions of the photovoltaic cells (or solar cells).

In the simplest way of operating, the polymer photovoltaic cells (or solar cells) with conventional architecture (namely the one known as “bulk heterojunction” architecture) are produced by introducing a thin layer (about 100 nanometers) of a mixture of the electron acceptor compound and electron donor compound, between two electrodes, usually constituted by Indium Tin Oxide (ITO, anode) and Aluminium (Al, cathode). To obtain a layer of this type, a solution of the two components is prepared.

Generally, to obtain such a thin layer, a solution of the two compounds is prepared and starting from this, a photoactive layer is then created on the first electrode, the hole contact layer (anode) [Indium Tin Oxide (ITO)], using suitable deposition techniques such as, for example, spin-coating, spray-coating, gravure printing, ink-jet printing, slot-die coating, etc. Finally, the counter, electrode, i.e. the electron contact layer (cathode), [the Aluminium (Al)] is deposited on the dried active layer. Optionally, between the electrodes and the photoactive layer, other additional layers may be inserted which may perform specific functions pertaining to electric, optical or mechanical properties.

In order to favour electron holes and, at the same time, to block or limit the electrons access to the hole contact layer (anode) [Indium Tin Oxide (ITO)], in general a further layer is deposited before the formation of the photoactive layer from the electron donor compound-electron acceptor compound solution as described above, in order to improve charge collection at the hole contact layer (anode) [Indium Tin Oxide (ITO)] and to inhibit recombination phenomena. Generally, said further layer is deposited starting from an aqueous suspension comprising PEDOT:PSS [poly(3,4-ethylenedioxythiophene): polystyrene sulfonate], using suitable coating and printing techniques such as, for example, spin-coating, spray-coating, gravure printing, ink-jet printing, slot-die coating, etc.

In the case of inverse architecture, the electrode made of Indium Tin Oxide (ITO) constitutes the electron contact layer (cathode), while the metallic electrode (generally, silver or gold) works as the hole contact layer (anode). Between the electrodes and the photoactive layer, also in this case other additional layers may be inserted. The interface between the photoactive layer and the electrodes must have properties that facilitate the charge collection.

To improve the performance of polymer photovoltaic cells (or solar cells) both with conventional architecture and with inverted structure, as reported above, other additional layers known as “buffer layers”, or “interlayers”, or “interfacial layers”, are used. Said “buffer layers” (here and hereinafter the term “buffer layers” is used to indicate said “other additional layers”) are thin layers (generally, having a thickness ranging from 0.5 nm to 100 nm) of inorganic, organic, or polymer materials, that are interposed between the electrodes and the photoactive layer, with the following aims:
to tune the work function of the electrode and making more ohmic the contact between the electrode(s) and the photoactive layer; and/or
to favour the transport of the charge carriers (electrons to the electron contact layer and holes to the hole contact layer); and/or
to disfavour the drifting of charge carriers having the opposite charge; and/or
to limit or avoid the exciton recombination at the organic phase/electrode(s) interface; and/or
to smooth the surface of the electrode(s) avoiding the formation of pinholes; and/or
to protect the photoactive layer from chemical reactions and damaging when deposition processes for electrode(s) production (for example, evaporation, sputtering, e-beam deposition, etc.) are performed; and/or
to limit or avoid the diffusion of metal impurities from the electrode(s) to the photoactive layer; and/or
to act as optical spacers.

In particular, cathodic buffer layers may: (i) produce an ohmic contact between the photoactive layer and the electron contact layer (cathode); (ii) favour the transport of electrons toward the electron contact layer (cathode); (iii) block the transport of holes toward the electron contact layer (cathode).

Buffer layers may be produced according to techniques known in the art such as, for example, spin-coating, spray-coating, printing techniques, sputtering, vacuum-evaporation, sol-gel deposition, etc. Further details relating to said techniques may be found, for example, in Pò R. et al., “Energy & Environmental Science” (2011), Vol. 4(2), pg. 285-310; Yin Z. et al., “Advanced Science” (2016), Vol. 3, 1500362 wherein, in Table 1, device characteristics of some representative organic solar cells (OSCs) using various electron-transporting cathode interface layer (CIL) materials are reported.

Hwang Y. H. et al., in “Journal of Materials Research” (2010), Vol. 25, No. 4, pg. 695-700, describe the fabrication and characterization of sol-gel-derived zinc oxide thin-film transistor. In particular, it is disclosed the preparation of a solution of a zinc acetate precursor by dissolving zinc acetate dehydrate in 2-methoxyethanol. Subsequently, in order to form a stable solution, the zinc acetate precursor was chelated with ethanolamine. The transparent and homogeneous solution obtained was spin-coated on SiO2/Si layer and subjected to two-step annealing process at 200° C. An oxygen plasma treating was applied immediately before the spin coating to remove unnecessary organics. Moreover, it is said that improvements of the film crystallinity and the interface between the semiconductor and gate dielectric are observed at high annealing temperature and that an additional postannealing process in N₂ surrounding may improve the electron conduction property of the film.

Lou X. et al., in “Transactions of Nonferrous Metal Society of China” (2007), Vol. 17, s814-s817, describe the preparation of a zinc oxide sol-gel precursor from zinc acetate dihydrate in isopropanol and 2-amminoethanol solutions. The ZnO film on quartz substrate is obtained by drying at 200° C., and thermal treatment in a furnace (400° C.-600° C.).

Huang J.-S. et al., DOI: 10.1109/NANO.2008.47, “2008 8th IEEE Conference on Nanotechnology”, describe the preparation of a ZnO sol-gel precursor from zinc acetate dihydrate in 2-methoxyethanol and 2-amminoethanol solutions. The ZnO-nanorod films are prepared by deposition on silicon wafers and treatment at 900° C.

Naik G. V. et al., in “Journal of The Electrochemical Society” (2011), Vol. 158(2), H85-H87, describe the polyols based sol-gel synthesis of zinc oxide thin films. In particular, a solution of zinc acetate dehydrate in solvent mixture of glycerol and ethylene glycol was spin coated onto oxidized silicon and glass substrates. The sol coated onto the substrates was hydrolyzed in humid air at 100° C., followed by bake at 150° C. for 30 minute and by pyrolysis/annealing in oxygen ambient for 30 minutes at 550° C.

Krebs F. C. et al., in “Solar Energy Materials & Solar Cells” (2009), Vol. 93, pg. 422-441, describe a complete process for production of flexible large area polymer solar cells entirely using screen printing: in particular, it was shown that inverted organic solar cell modules may be produced entirely with screen printing. Moreover, it is suggested that the future work should focus on unifying stability, efficiency and process, and especially with respect to the latter it should emphasized that a combination of roll-to-roll (R2R) compatible printing techniques is probably the way towards the optimum polymer solar cells.

Hübler A. et al., in “Advanced Energy Materials” (2011), Vol. 1, pg. 1018-1022, describe the fabrication of inverted solar cells on paper with an efficiency of 1.31% by using a combination of gravure printing and flexography printing.

Voigt M. M. et al., in “Solar Energy Materials Solar Cells” (2011), Vol. 95, pg. 731-734 and in “Solar Energy Materials Solar Cells” (2012), Vol. 105, pg. 77-85, describe the fabrication of inverted organic photovoltaic devices by gravure printing on flexible substrate and the influence of ink properties on film quality and device performance, respectively: it has to be noted that the power conversion efficiency (PCE) is 0.6% and 1.2%, respectively.

It is known that inverted polymer solar cells with zinc oxide cathodic buffer layer exhibit a characteristic S-Shaped current-voltage curve such as disclosed, for example, in: Manor A. et al., “Solar Energy Materials & Solar Cells” (2012), Vol. 98, pg. 491-493; Tromholt T. et al., “Nanotechnology” (2011), Vol. 22, pg. 225401 (6 pp); Lilliedal M. R. et al., “Solar Energy Materials & Solar Cells” (2010), Vol. 94, pg. 2018-2031; Jouane Y. et al., “Journal of Materials Chemistry” (2012), Vol. 22, pg. 1606-1612. This behaviour is attributed to the low zinc oxide conductance and poor charge extraction and implies lower short-circuit current density (J_{sc}), lower open circuit voltage (V_{oc}) and even lower fill factor (FF). Physical post-treatments on the device (e.g., UV irradiation) are suggested to overcome this problem and thus attaining acceptable power conversion efficiency (PCE), but they introduce undesirable and expensive additional steps in the fabrication processes. Therefore a simple method to fabricate efficient devices with zinc oxide (ZnO) interlayers is highly desirable.

It is known that inverted polymer photovoltaic cells (or solar cells) with zinc oxide cathodic buffer layer generally have a lower power conversion efficiency (PCE) than the conventional cells with a top electron extraction layer. It is known, in fact, that up to 30% of the atomic bonds in zinc oxide colloidal nanoparticles usually used as electron extraction material for said zinc oxide cathodic buffer layer are dandling bonds and these defects give rise to a high density recombination center resulting in low power conversion efficiency (PCE).

Chen S. et al., in “Advanced Energy Materials” (2012), Vol. 2, pg. 1333-1337, describe a process to obtain inverted polymer solar cells with reduced interface recombination which leads to low efficiencies of the same, through a simple UV-ozone treatment (UVO treatment) of the zinc oxide nanoparticles (ZnO NP) film (i.e. of the electron extraction layer) immediately after the deposition of said film onto the ITO coated glass substrate. It is said that the UVO treatment is able to passivate said defects, so obtaining enhancements in short-circuit current density (J_{sc}) and hence power conversion efficiency (PCE).

### SUMMARY

Applicant has faced the problem of finding a process for producing an inverted polymer photovoltaic cell (or solar cell) endowed with good power conversion efficiency (PCE) and, in particular, being able to maintain said power conversion efficiency (PCE) stable over time.

Applicant has found that the use of a cathodic buffer layer obtained by forming a layer onto the electron contact layer (cathode) of a composition comprising at least one zinc oxide and/or titanium dioxide or a precursor thereof, at least one organic solvent and at least one polymer soluble in said organic solvent and plasma treating said layer formed onto said electron contact layer, allows to obtain an inverted polymer photovoltaic cell (or solar cell) which is endowed with good power conversion efficiency (PCE) and, in particular, which are able to maintain said power conversion efficiency (PCE) stable over time.

Therefore, the present disclosure provides a process for producing an inverted polymer photovoltaic cell (or solar cell) comprising the following steps:
providing an electron contact layer (cathode);
depositing a cathodic buffer layer onto said electron contact layer;
depositing a photoactive layer comprising at least one photoactive organic polymer and at least one organic electron acceptor compound onto said cathodic buffer layer;
depositing an anodic buffer layer onto said photoactive layer;
providing a hole contact layer (anode);
   wherein the step of depositing said cathodic buffer layer comprises:
forming a layer onto said electron contact layer of a composition comprising at least one zinc oxide and/or titanium dioxide or a precursor thereof, at least one organic solvent and at least one polymer soluble in said organic solvent;
plasma treating said layer formed onto said electron contact layer so as to form the cathodic buffer layer.

For the purpose of the present description and of the following claims, the definitions of the numeric ranges always include the extremes unless specified otherwise.

For the purpose of the present description and of the following claims, the wording “soluble in said organic solvent” means that the polymer dissolves at a concentration of about 0.1% by weight to about 50% by weight, preferably of about 0.1% by weight to about 5% by weight, in said organic solvent, at room temperature (25° C.).

In accordance with a preferred embodiment of the present disclosure, said electron contact layer (cathode) may be made of a material selected, for example, from: indium tin oxide (ITO), tin oxide doped with fluorine (FTO), zinc oxide doped with aluminum (AZO), zinc oxide doped with gadolinium oxide (GZO); or it may be constituted by grids of conductive material, said conductive material being preferably selected, for example, from silver (Ag), copper (Cu), graphite, graphene, and by a transparent conductive polymer, said transparent conductive polymer being preferably selected, for example, from PEDOT:PSS [poly(3,4-ethylenedioxythiophene):polystyrene sulfonate], polyaniline (PANI); or it may be constituted by a metal nanowire-based ink, said metal being preferably selected, for example, from silver (Ag), copper (Cu). Indium tin oxide (ITO) is preferred. Said electron contact layer (cathode) may be obtained by techniques known in the state of the art such as, for example, electron beam assisted deposition, sputtering. Alternatively, said electron contact layer (cathode) may be obtained through deposition of said transparent conductive polymer via spin coating, or gravure printing, or flexographic printing, or slot die coating, preceded by deposition of said grids of conductive material via evaporation, or screen-printing, or spray-coating, or flexographic printing. Alternatively, said electron contact layer (cathode) may be obtained through deposition of said metal nanowire-based ink through spin coating, or gravure printing, or flexographic printing, or slot die coating. The deposition may take place on the support layer selected from those listed below.

In accordance with a preferred embodiment of the present disclosure, said electron contact layer (cathode) may be associated with a support layer that may be made of a rigid transparent material such as, for example, glass, or flexible material such as, for example, polyethylene terephthalate (PET), polyethylene naphthalate (PEN), polyethyleneimine (PI), polycarbonate (PC), polypropylene (PP), polyimide (PI), triacetyl cellulose (TAC), or their copolymers. Polyethylene terephthalate (PET) is preferred.

In accordance with a preferred embodiment of the present disclosure, said photoactive organic polymer may be selected, for example, from:
(a) polythiophenes such as, for example, poly(3-hexylthiophene) (P3HT) regioregular, poly(3-octylthiophene), poly(3,4-ethylenedioxythiophene), or mixtures thereof;
(b) conjugated alternating or statistical copolymers comprising:
   at least one benzotriazole unit (B) having general formula (Ia) or (Ib):

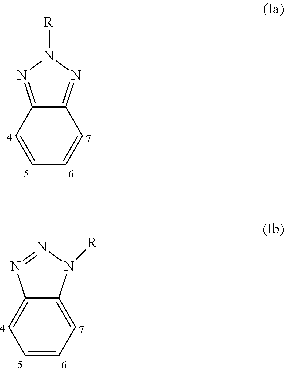

wherein the group R is selected from alkyl groups, aryl groups, acyl groups, thioacyl groups, said alkyl, aryl, acyl and thioacyl groups being optionally substituted;
at least one conjugated structural unit (A), wherein each unit (B) is connected to at least one unit (A) in any of positions 4, 5, 6, or 7, preferably in positions 4 or 7;
(c) conjugated alternating copolymers comprising benzothiadiazole units such as, for example, PCDTBT {poly[N-9″-heptadecanyl-2,7-carbazole-alt-5,5-(4′, 7′-di-2-thienyl-2′,1′,3′-benzothiadiazole]}, PCPDTBT {poly [2,6-(4,4-bis-(2-ethylhexyl)-4H-cyclopenta [2,1-b; 3,4-b′]-dithiophene)-alt-4,7-(2,1,3-benzotiadiazole)]};
(d) conjugated alternating copolymers comprising thieno[3,4-b]pyrazidine units;
(e) conjugated alternating copolymers comprising quinoxaline units;
(f) conjugated alternating copolymers comprising monomeric silylated units such as, for example, copolymers of 9,9-dialkyl-9-silafluorene;
(g) conjugated alternating copolymers comprising condensed thiophene units such as, for example, copolymers of thieno[3,4-b] thiophene and of benzo [1,2-b: dithiophene;
(h) conjugated alternating copolymers comprising benzothiadiazole or naphtothiadiazole units substituted with at least one fluorine atom and thiophene units substituted with at least one fluorine atom such as, for example, PffBT4T-2OD {poly[(5,6-difluoro-2,1,3-benzothiadiazol-4,7-diyl)-alt-(3,3″-(2-octyldodecyl)-2,2′,5′,2″;5″,2″-quaterthiophene-5,5″-diil)]}, PBTff4T-2OD {poly [(2,1,3-benzothiadiazole-4,7-diyl)-alt-(4′,3″-difluoro-3,3′″-(2-octyldodecyl)-2,2′;5′,2″;5″,2′″-quaterthiophene-5,5″-diyl)]}, PNT4T-2OD {poly(naphtho[1,2-c:5,-c′]bis [1,2,5] thiadiazole-5,10-diyl)-alt-(3,3″-(2-octyldodecyl)-2,2′;5′,2″;5″,2′″-quaterthiophene-5,5″-diyl)];
(i) conjugated copolymers comprising thieno[3,4-c]pyrrole-4,6-dione units such as, for example, PBDTTPD {poly [[5-(2-ethylhexyl)-5,6-dihydro-4,6-dioxo-4H-thieno[3,4-c]pyrrole-1,3-diyl][4,8-bis[(2-ethylhexyl)oxy]benzo-[1,2-b:4,5-b′]dithiophene-2,6-diyl]};
(l) conjugated copolymers comprising thienothiophene units such as, for example, PTB7 {poly({4,8-bis[(2-ethylhexyl)oxy]benzo[1,2-b′]dithiophene-2,6-diyl}-{3-fluoro-2-[(2-ethylhexyl)carbonyl]thieno [3,4-b]thiophenediyl}};
(m) polymers comprising a derivative of indacen-4-one having general formula (III), (IV) or (V):

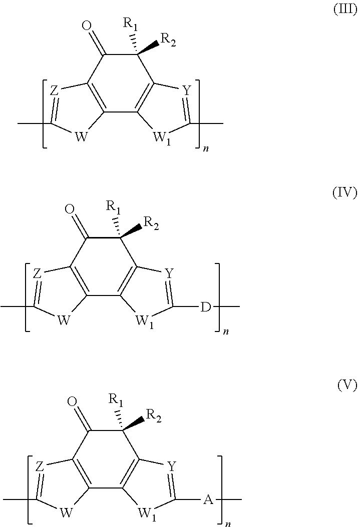

wherein:
   W and W₁, identical or different, preferably identical, represent an oxygen atom; a sulfur atom; an N—R₃ group wherein R₃ represents a hydrogen atom, or is selected from linear or branched C₁-C₂₀ alkyl groups, preferably C₂-C₁₀;
   Z and Y, identical or different, preferably identical, represent a nitrogen atom; or a C—R₄ group wherein R₄ represents a hydrogen atom, or is selected from linear or branched C₁-C₂₀ alkyl groups, preferably C₂-C₁₀, optionally substituted cycloalkyl groups, optionally substituted aryl groups, optionally substituted heteroaryl groups, linear or branched C₁-C₂₀ alkoxy groups, preferably C₂-C₁₀, R₅—O—[CH₂—CH₂—O]ₙ— polyethylenoxyl groups wherein R₅ is selected from linear or branched C₁-C₂₀ alkyl groups, preferably C₂-C₁₀, and n is an integer ranging from 1 to 4, —R₆—OR₇ groups wherein R₆ is selected from linear or branched C₁-C₂₀ alkyl groups, preferably C₂-C₁₀, and R₇ represents a hydrogen atom or is selected from linear or branched C₁-C₂₀ alkyl groups, preferably C₂-C₁₀, or is selected from R₅—[—OCH₂—CH₂—]ₙ— polyethylenoxyl groups wherein R₅ has the same meanings reported above and n is an integer ranging from 1 to 4, —COR₈ groups wherein R₈ is selected from linear or branched C₁-C₂₀ alkyl groups, preferably C₂-C₁₀; —COOR₉ groups wherein R₉ is selected from linear or branched C₁-C₂₀ alkyl groups, preferably C₂-C₁₀; or represent a —CHO group, or a cyano group (—CN);
   R₁ and R₂, identical or different, preferably identical, are selected from linear or branched C₁-C₂₀ alkyl groups, preferably C₂-C₁₀; optionally substituted cycloalkyl groups; optionally substituted aryl groups; optionally substituted heteroaryl groups; linear or branched C₁-C₂₀ alkoxy groups, preferably C₂-C₁₀; R₅—O—[CH₂—CH₂—O]ₙ— polyethylenoxyl groups wherein R₅ has the same meanings reported above and n is an integer ranging from 1 to 4; —R₆—OR₇ groups wherein R₆ and R₇ have the same meanings reported above; —COR₈ groups wherein R₈ has the same meanings as above; or —COOR₉ groups wherein R₉ has the same meanings as above; or represent a —CHO group, or a cyano group (—CN);
   D represents an electron-donor group;
   A represents an electron acceptor group;
   n is an integer ranging from 10 to 500, preferably ranging from 20 to 300,
      or mixtures thereof.

More details on conjugated alternating or statistical copolymers (b) comprising at least one benzotriazole unit (B) and at least one conjugated structural unit (A) and on the process for their preparation may be found, for example, in International Patent Application WO 2010/046114 in the name of the Applicant.

More details on conjugated alternating copolymers comprising benzothiadiazole units (c), conjugated alternating copolymers comprising thieno[3,4-b]pyrazidine units (d), conjugated alternating copolymers comprising quinoxaline units (e), conjugated alternating copolymers comprising monomeric silylated units (f), conjugated alternating copolymers comprising condensed thiophene units (g), may be found, for example, in Chen J. et al., “Accounts of Chemical Research” (2009), Vol. 42, No. 11, pg. 1709-1718; Po' R. et al., “Macromolecules” (2015), Vol. 48(3), pg. 453-461.

More details on conjugated alternating copolymers comprising benzothiadiazole or naphtothiadiazole units substituted with at least one fluorine atom and thiophene units substituted with at least one fluorine atom (h) may be found, for example, in Liu Y. et al., “Nature Communications” (2014), Vol. 5, Article no. 5293 (DOI:10.1038/ncomms6293).

More details on conjugated copolymers comprising thieno[3,4-c]pyrrole-4,6-dione units (i) may be found, for example, in Pan H. et al., “Chinese Chemical Letters” (2016), Vol. 27, Issue 8, pg. 1277-1282.

More details on conjugated copolymers comprising thienothiophene units (I) may be found, for example, in Liang Y. et al., “Journal of the American Chemical Society” (2009), Vol. 131(22), pg. 7792-7799; Liang Y. et al., “Accounts of Chemical Research” (2010), Vol. 43(9), pg. 1227-1236.

More details on polymers comprising a derivative of indacen-4-one (q) may be found, for example, in International Patent Application WO 2016/180988 in the name of the Applicant.

In accordance with a particularly preferred embodiment of the present disclosure, said photoactive organic polymer may be selected, for example, from: PffBT4T-2OD {poly [(5,6-difluoro-2,1,3-benzothiadiazol-4,7-diyl)-alt-(3,3″-(2-octyl-dodecyl)-2,2′,5′,2″;5″,2′″-quaterthiophene-5,5″-diyl)]}, PBDTTPD {{poly [[5-(2-ethylhexyl)-5,6-dihydro-4,6-dioxo-4H-thieno [3,4-c]pyrrole-1,3-diyl][4,8-bis [(2-ethylhexyl)oxy]benzo[1,2-b:4,5-b]dithiophene-2,6-diyl]}, PTB7 {poly(l4,8-bis[(2-ethylhexyl)oxo]benzo[1,2-b:4,5-b′]dithiophene-2,6-diyl}{3-fluoro-2-[(2-ethylhexyll)carbonyl]thieno[3,4-b]thiophenediyl})}; or mixtures thereof. Poly(3-hexylthiophene) (P3HT) regioregular is preferred.

In accordance with a preferred embodiment of the present disclosure, said organic electron acceptor compound may be selected, for example, from: fullerene derivatives such as, for example, [6,6]-phenyl-C₆₁-butyric acid methyl ester (PC₆₁BM), [6,6]-phenyl-C₇₁-butyric acid methyl ester (PC₇₁BM), bis-adduct indene-C₆₀ (ICBA), bis(1-[3-(methoxycarbonyl)propyl]-1-phenyl)-[6,6]C₆₂ (Bis-PCBM), or mixtures thereof [6,6]-Phenyl-C₆₁-butyric acid methyl ester (PC₆₁BM) is preferred.

In accordance with a further preferred embodiment of the present disclosure, said organic electron acceptor compound may be selected, for example, from: non-fullerene, optionally polymeric, compounds such as, for example, compounds based on perylene-diimides or naphthalene-diimides and fused aromatic rings; indacenothiophene with terminal electron-poor groups; compounds having an aromatic core able to symmetrically rotate such as, for example, derivatives of corannulene or truxenone; or mixtures thereof 3,9-Bis{2-methylene-[3-(1,1-dicyanomethylene)-indanone]}-5,5,11,11-tetrakis(4-hexylphenyl)-dithieno[2,3-d:2′,3′-d′]-s-indaceno[1,2-b:5,6-b′]-dithiophene, poly {[N,N′-bis (2-octyldodecyl)-1,4,5,8-naftalenediimide-2,6-diyl]-alt-5,5′-(2,2′-bithiophene)}, are preferred.

More details on said non-fullerene compounds may be found, for example, in Nielsen C. B. et al., “Accounts of Chemical Research” (2015), Vol. 48, pg. 2803-2812; Zhan C. et al., “RSC Advances” (2015), Vol. 5, pg. 93002-93026.

Said photoactive layer may be obtained by depositing on said cathodic buffer layer a solution containing at least one photoactive organic polymer and at least one organic electron acceptor compound, selected from those mentioned above, by using appropriate deposition techniques such as, for example, spin-coating, spray-coating, ink-jet printing, slot die coating, gravure printing, screen printing.

In accordance with a preferred embodiment of the present disclosure, said anodic buffer layer may be selected, for example, from: PEDOT:PSS [poly(3,4-ethylenedioxythiophene):polystyrene sulfonate], polyaniline (PANI), or mixtures thereof. PEDOT:PSS [poly(3,4-ethylenedioxythiophene): polystyrene sulfonate] is preferred.

Dispersions or solutions of PEDOT:PSS [poly(3,4-ethylenedioxythiophene):polystyrene sulfonate] that may be advantageously used for the purpose of the present disclosure and that are currently available on the market are the products Clevios™ by Heraeus, Orgacon™ by Agfa.

In accordance with a further preferred embodiment of the present disclosure, said anodic buffer layer may be selected, for example, from hole transporting material obtained through a process comprising: (a) reacting at least one heteropoly acid containing at least one transition metal belonging to group 5 or 6 of the Periodic Table of the Elements such as, for example, phosphomolybdic acid hydrate {H₃[P(MoO₃)₁₂O₄].nH₂O}, phosphomolybdic acid {H₃[P(MoO₃)₁₂O₄]} in alcoholic solution, silicotungstic acid hydrate {H₄[Si(WO₃)₁₂O₄].nH₂O}, or mixtures thereof; with (b) an equivalent amount of at least one salt or one complex of a transition metal belonging to group 5 or 6 of the Periodic Table of the Elements with an organic anion, or with an organic ligand such as, for example, molybdenum(VI) dioxide bis(acetylacetonate) (Cas No. 17524-05-9), vanadium(V) oxytriisopropoxide (Cas No. 5588-84-1), bis (acetylacetonate) oxovanadium (IV) (Cas No. 3153-26-2), or mixtures thereof; in the presence of at least one organic solvent selected from alcohols, ketones, esters, preferably from alcohols such as, for example, iso-propanol, n-butanol.

Further details relating to said hole transporting materials may be found, for example in the International Patent Application WO 2018/122707, as well as in the Italian Patent Application MI2017000020775, in the name of the Applicant, both herewith enclosed as reference.

For the purpose of improving the deposition and the properties of said anodic buffer layer, one or more additives may be added to said dispersions or solutions such as, for example: polar solvents such as, for example, alcohols (for example, methanol, ethanol, propanol), dimethylsulfoxide, or mixtures thereof; anionic surfactants such as, for example, carboxylates, α-olefin sulfonate, alkylbenzene sulfonates, alkyl sulfonates, esters of alkyl ether sulfonates, triethanolamine alkyl sulfonate, or mixtures thereof; cationic surfactants such as, for example, alkyltrimethylammonium salts, dialkyldimethylammonium chlorides, alkyl-pyridine chlorides, or mixtures thereof; ampholytic surfactants such as, for example, alkyl carboxybetaine, or mixtures thereof; non-ionic surfactants such as, for example, carboxylic diethanolamides, polyoxyethylene alkyl ethers, polyoxyethylene alkyl phenyl ethers, or mixtures thereof; polar compounds (for example, imidazole), or mixtures thereof; or mixtures thereof. More details on the addition of said additives may be found, for example, in: Synooka O. et al., “ACS Applied Materials & Interfaces” (2014), Vol. 6(14), pg. 11068-11081; Fang G. et al., “Macromolecular Chemistry and Physics” (2011), Vol. 12, Issue 17, pg. 1846-1851.

Said anodic buffer layer may be obtained by depositing the PEDOT:PSS [poly(3,4-ethylenedioxythiophene):polystyrene sulfonate], or polyaniline (PANI), in the form of a dispersion or solution, on the photoactive layer through deposition techniques known in the state of the art such as, for example, vacuum evaporation, spin coating, drop casting, doctor blade casting, slot die coating, gravure printing, flexographic printing, knife-over-edge-coating, spray-coating, screen-printing.

In accordance with a preferred embodiment of the present disclosure, said hole contact layer (anode) may be made of metal, said metal being preferably selected, for example, from silver (Ag), gold (Au), aluminum (Al); or it may be constituted by grids of conductive material, said conductive material being preferably selected, for example, from silver (Ag), copper (Cu), graphite, graphene, and by a transparent conductive polymer, said transparent conductive polymer being preferably selected from PEDOT:PSS [poly(3,4-ethylenedioxythiophene):polystyrene sulfonate], polyaniline (PANI); or it may be constituted by a metal nanowire-based ink, said metal being preferably selected, for example, from silver (Ag), copper (Cu). Silver (Ag) is preferred.

Said hole contact layer (anode) may be obtained by depositing said metal onto said anodic buffer layer through deposition techniques known in the state of the art such as, for example, vacuum evaporation, flexographic printing, knife-over-edge-coating, spray-coating, screen-printing. Alternatively, said hole contact layer (anode) may be obtained through deposition on said anodic buffer layer of said transparent conductive polymer through spin coating, or gravure printing, or flexographic printing, or slot die coating, followed by deposition of said grids of conductive material via evaporation, or screen-printing, or spray-coating, or flexographic printing. Alternatively, said hole contact layer (anode) may be obtained through deposition on said anodic buffer layer of said metal nanowire-based ink through spin coating, or gravure printing, or flexographic printing, or slot die coating.

In accordance with a preferred embodiment of the present disclosure, said zinc oxide precursor, may be selected, for example, from zinc salts and zinc complexes such as, for example: zinc acetate, zinc formiate, zinc acetylacetonate, zinc alcoholates (for example, methoxide, ethoxide, propoxide, iso-propoxide, butoxide), zinc carbamate, zinc bis(alkylamide(s), zinc dialkyls or diaryls (for example, diethylzinc, diphenylzinc), or mixtures thereof.

In accordance with a preferred embodiment of the present disclosure, said titanium oxide precursor, may be selected, for example, from titanium salts and titanium complexes such as, for example: titanium acetate, titanium formiate, titanium acetylacetonate, titanium alcoholates (for example, methoxide, ethoxide, propoxide, iso-propoxide, butoxide), titanium carbamate, titanium bis(alkylamide(s), titanium dialkyls or diaryls (for example, diethyltitanium, diphenyltitanium), or mixtures thereof.

In accordance with a particularly preferred embodiment of the present disclosure, said at least one zinc oxide is in the form of colloidal nanoparticles. Preferably, colloidal zinc oxide nanoparticles have an average particle size ranging from 5 nm to 50 nm, preferably ranging from 10 nm to 40 nm.

In accordance with a preferred embodiment of the present disclosure, the amount of said zinc oxide and/or titanium dioxide or precursor thereof in said composition, is ranging from 1% by weight to 30% by weight, preferably is ranging from 2% by weight to 10% by weight, with respect to the total weight of the composition.

In accordance with a preferred embodiment of the present disclosure, said at least one organic solvent may be selected, for example, from: alcohols such as, for example, methanol, ethanol, propanol, iso-propanol, butanol, or mixtures thereof aromatic solvents such as, for example, toluene, o-xylene, m-xylene, p-xylene, or mixture thereof; aliphatic solvents such as, for example, hexane, heptane, or mixtures thereof; heteroaromatic solvents such as, for example, tetrahydrofuran, or mixtures thereof; heterocyclic solvents such as, for example dioxane, or mixtures thereof; oxygenated solvents such as, for example, diethyl ether, dimethoxyethane, or mixtures thereof; polar solvents such as, for example, acetonitrile, N,N-dimethylformamide, N,N-dimethylacetamide, or mixtures thereof. Alcohols are preferred and ethanol is particularly preferred.

In accordance with a preferred embodiment of the present disclosure, said at least one polymer soluble in said organic solvent may be selected, for example from: poly(vinyllactames) such as, for example, poly(N-vinylpyrrolidone) (PVP), poly(N-vinylcaprolactam), poly(N-vinylbutyrolactam), or mixtures thereof; poly(N-acylimines such as, for example, poly(N-acetylimine), poly(N-propanoylimine), or mixtures thereof; N,N-dialkyl substituted poly(acrylamides) such as, for example, poly(N,N-dimethylacrylamide), poly(N,N-diethylacrylamide), or mixtures thereof; poly[hydroxyalkyl(meth)acrylates such as, for example, poly(2-hydroxethylmethacrylate), or mixtures thereof; poly(vinylpyridines) such as, for example, poly(-vinylpiridine), poly(4-vinylpiridine), or mixtures thereof; poly(alkylglycols) such as, for example, poly(ethyleneglycol), poly(propyleneglycol), or mixtures thereof; or mixtures thereof. Poly(N-vinylpyrrolidone) (PVP) is preferred.

In accordance with a preferred embodiment of the present disclosure, the amount of said polymer in said composition, is ranging from 0.02% by weight to 10% by weight, preferably ranging from 0.05% by weight to 2% by weight, with respect to the total weight of the composition.

In accordance with a preferred embodiment of the present disclosure, said plasma treating may be carried out in the presence of an inorganic gas such as, for example, argon (Ar), helium (He), nitrogen (N₂), oxygen (O₂), or mixtures thereof. A mixture of argon (Ar) and nitrogen (N₂) is preferred.

In accordance with a preferred embodiment of the present disclosure, said plasma treating may be carried out under a discharge power ranging from 10 W to 1000 W, preferably ranging from 100 W to 500 W.

The plasma treating may be carried out in a plasma generating apparatus known in the art. For example, the plasma treating may be carried out in a plasma generating apparatus of an internal electrode-type. However, an external electrode-type apparatus may be used, if necessary. Capacitive coupling such as, for example, a coil furnace or inductive coupling may be used. The shape of the electrodes is not specifically limited. Thus, the electrodes may be in various form such as, for example, flat plate-like, ring-like, rod-like, cylinder-like form. The surface of the electrodes is preferably provided with a coat such as, for example, enamel coat, a glass coat, a ceramic coat. Further, an electrically grounded inside metal wall of the treatment apparatus may be used as one of the electrodes.

Preferably, the process according to the present disclosure is carried out continuously through roll-to-roll (R2R) printing using, in particular, gravure printing and rotary screen-printing deposition technique. Further details about said roll-to-roll (R2R) printing may be found, for example, in Välimäki M. et al., “Nanoscale” (2015), Vol. 7, pg. 9570-9580.

As mentioned above, the present disclosure also relates to an inverted polymer photovoltaic cell (or solar cell) obtained with the above reported process.

In accordance with a preferred embodiment of the present disclosure, in the inverted polymer photovoltaic cell (or solar cell) according to the present disclosure:
the electron contact layer (cathode) may have a thickness ranging from 50 nm to150 nm, preferably ranging from 80 nm to 130 nm;
the cathodic buffer layer may have a thickness ranging from 10 nm to 100 nm, preferably ranging from 20 nm to 60 nm;
the photoactive layer may have a thickness ranging from 50 nm to 250 nm, preferably ranging from 100 nm to 200 nm;
the anodic buffer layer may have a thickness ranging from 200 nm to 2000 nm, preferably ranging from 500 nm to 1500 nm;
the hole contact layer (anode) may have a thickness ranging from 5000 nm to 15000 nm, preferably ranging from 8000 nm to 12000 nm.

### BRIEF DESCRIPTION OF THE DRAWINGS

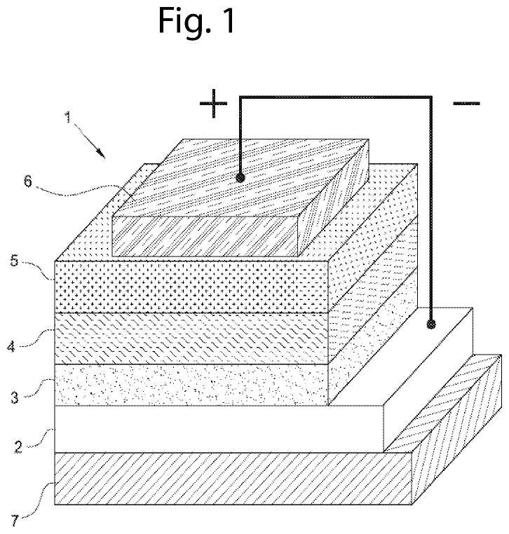

The present disclosure will now be illustrated in more detail through an embodiment with reference to FIG. 1 provided below which represents a cross sectional view of an inverted polymer photovoltaic cell (or solar cell) according to the present disclosure.

### DETAILED DESCRIPTION OF THE DRAWINGS

With reference to FIG. 1, the inverted polymer photovoltaic cell (or solar cell) (1) comprises:
a transparent support (7), for example a polyethylene terephthalate (PET);
an electron contact layer (cathode) (2), for example an indium tin oxide (ITO) cathode;
a cathodic buffer layer (3), comprising, for example, a composition comprising colloidal zinc oxide nanoparticle, ethanol and poly(N-vinylpyrrolidone) (PVP) obtained through roll-to-roll (R2R) gravure printing and subjected to plasma treating;
a layer of photoactive material (4) comprising at least one photoactive organic polymer, for example, poly(-hexylthiophene) (P3HT) regioregular and at least one non-functionalized fullerene, for example, methyl ester of [6,6]-phenyl-C₆₁-butyric acid (PC₆₁BM) obtained through roll-to-roll (R2R) gravure printing;
an anodic buffer layer (5), comprising, for example, PEDOT:PSS [poly(3,4-ethylenedioxythiophene):polystyrene sulfonate] obtained through roll-to-roll (R2R) rotary screen printing;
an hole contact layer (anode) (6), for example a silver (Ag) anode, obtained through roll-to-roll (R2R) rotary screen printing.

For the purpose of understanding the present disclosure better and to put it into practice, below are some illustrative and non-limiting examples thereof.

### Example 1 (Disclosure)

Solar Cell with Cathodic Buffer Layer Comprising Zinc Oxide and PVP Plasma Treated

A polymer-based device was prepared on top of a ITO (indium tin oxide)-coated PET (polyethyleneterephthalate) (Solutia/Eastman) substrate (surface resistivity equal to 40 Ω/sq-60 Ω/sq as disclosed in Välimäki M. et al. above reported. The PET and ITO thicknesses were equal to 125 μm and 0.125 μm, respectively. As a first process step, the ITO was patterned with Isishape HiperEtch 09S Type 40 paste (Merck) as a negative image to the desired pattern. R2R rotary screen printing was performed with a printing speed of 1.1 m/min. After printing, the printed film continued directly into the R2R hot air drying units set to a temperature of 140° C. for 218 seconds. The paste was washed off in baths of water and 2-propanol. After patterning, the surface was ultrasonically washed and dried in the R2R process.

The substrate thus treated was ready for the deposition of the cathodic buffer layer. For that purpose, to a 500 g of colloidal zinc oxide nanoparticle suspension in ethanol (ZnO Nanoparticles, 5 wt %, 15 nm) (Avantana—Switzerland), 0.51 g of poly(N-vinylpyrrolidone) (PVP) (Aldrich) were added: the whole was maintained, under stirring, at ambient temperature (25° C.), overnight, obtaining an homogeneous suspension which was kept in an ultrasonic bath for 10 minutes before printing. Subsequently, the obtained suspension was deposited through R2R gravure-printing on the substrate, operating at a speed equal to 8 m/min, at nip pressure equal to 1 bar-1.5 bar. The printing cylinder contains engravings with a line density equal to 120 lines/cm. Immediately after the deposition of the cathodic buffer layer, everything was positioned in an in-line plasma unit and was subjected to plasma treating. The plasma treating was performed for the printed and dried cathodic buffer layer in the R2R line at a speed of 2 m/min, using a mixture of N₂/Ar (1/3, v/v) and 200 W discharge power in atmospheric pressure: as the R2R plasma process is not performed under vacuum and the plasma unit is open to air, there is always some (unknown) amount of oxygen also present, which might have an effect on the plasma process.

The cathodic buffer layer thus obtained had a thickness equal to 25 nm-50 nm.

A solution of poly(-hexylthiophene) (P3HT) regioregular (Rieke Metals) and [6,6]-phenyl-C₆₁-butyric acid methyl ester (PC₆₁BM) (purity 99.5%-Nano-C), 1:0.63 (w:w) in 1,2-dichlorobenzene was prepared with a total concentration of P3HT equal to 0.13 g/ml: said solution was left, under agitation, at 45° C., overnight: subsequently, the solution was left to cool to ambient temperature (25° C.). The photoactive layer was deposited, starting from the solution thus obtained, through R2R gravure-printing, operating at a speed equal to 8 m/min and at nip pressure equal to 1 bar-1.5 bar. The printing cylinder contains engravings with a line density equal to 120 lines/cm. The thickness of the photoactive layer was equal to 175 nm. Straight after printing, the (P3HT):(PC₆₁BM) layer was dried at 120° C., for 30 seconds, in an oven, in ambient air.

The anodic buffer layer was deposited onto the photoactive layer thus obtained, starting from a highly viscous suspension comprising PEDOT:PSS [poly(3,4-ethylenedioxythiophene):polystyrene sulfonate] (Orgacon EL-P 5015—Agfa) with a concentration of PEDOT:PSS equal to 5% by weight, trough R2R rotary screen printing performed with a printing speed of 2 m/min: straight after the deposition of the anodic buffer layer, the device was dried, at 130° C., for 2 minutes, in an oven, in ambient air. The thickness of the anodic buffer layer was equal to 1000 nm.

The silver (Ag) hole contact layer (anode) was deposited onto said anodic buffer layer, starting from the thermoplastic polymer thick-film silver (XPVS-670-PPG Industrial Coatings) trough R2R rotary screen printing using 275 L (meshes/inch) screen (RVS) from Gallus, performed with a printing speed of 2 m/min: straight after the deposition of the hole contact layer (anode), the device was dried, at 130° C., for 2 minutes, in an oven, in ambient air. The thickness of the hole contact layer (anode) was equal to 10000 nm and the active area of the device was ranging from 19 cm².

The obtained device was encapsulated inside a nitrogen glove box using a laminator which activates the pressure sensitive adhesive. The encapsulation material used were: (i) a pressure sensitive adhesive (EL-92734 from Adhesives Research) and (ii) a UV-blocking flexible barrier film (ATCJ from Amcor, wavelengths below 360 nm are blocked), using a copper tape for making the contacts.

The thicknesses were measured with a Dektak 150 profilometer (Veeco Instruments Inc.).

The electrical characterization of the device obtained was performed in said glove box at ambient temperature (25° C.). The current-voltage curves (I-V) were acquired with a Keithley® 2600A multimeter connected to a PC for data collection. The photocurrent was measured by exposing the device to the light of a Solartest 1200 (Atlas) solar simulator, able to provide AM 1.5 G radiation with an intensity of 100 mW/cm² (1 sun). The obtained power conversion efficiency (PCE) is reported in Table 1, measured using a calibrated reference solar cell (Si-reference solar cell) filtered with KG5 filter.

Furthermore the obtained device was subjected to accelerated ageing test in Atlas XXL+ weathering chamber and frequently electrically characterized during 7000 hours (offline measurement, AM 1.5). The voltage range for the measurements was from −1 V to 14 V. The aging conditions were 65° C. and 50% relative humidity (R.H.), under constant sunlight at an exposure irradiance level of 42 W/m² (300 nm-400 nm), according to the ISOS-L-3 protocol disclosed in Roesch R. et al., “Advanced Energy Materials” (2015), Vol. 5, 1501407.

The photocurrent was measured offline from −1 V to 14 V as reported above up to 7000 hours: the obtained power conversion efficiency (PCE) is reported in Table 1.

### Example 2 (Comparative)

Solar Cell with Cathodic Buffer Layer Comprising Zinc Oxide Plasma Treated

A polymer-based device was prepared operating according to Example 1, the only difference being the cathodic buffer layer which is made from colloidal zinc oxide nanoparticle suspension in ethanol (ZnO Nanoparticles, 5 wt %, 15 nm) (Avantama) without the addition of poly(N-vinylpyrrolidone) (PVP).

The obtained device was subjected to the characterizations reported in Example 1: the obtained power conversion efficiency (PCE) is reported in Table 1.

### Example 3 (Comparative)

Solar Cell with Cathodic Buffer Layer Comprising Zinc Oxide and PVP

A polymer-based device was prepared operating according to Example 1, the only difference being the cathodic buffer layer is not subjected to plasma treating.

The obtained device was subjected to the characterizations reported in Example 1: the obtained power conversion efficiency (PCE) is reported in Table 1.

### Example 4 (Comparative)

Solar Cell with Cathodic Buffer Comprising Zinc Oxide

A polymer-based device was prepared operating according to Example 1, the only difference being the cathodic buffer layer which is made from colloidal zinc oxide nanoparticle suspension in ethanol (ZnO Nanoparticles, 5 wt %, 15 nm) (Nanograde) and is not subjected to plasma treatment.

The obtained device was subjected to the characterizations reported in Example 1: the obtained power conversion efficiency (PCE) is reported in Table 1.

The data reported in Table 1 represent the mean values obtained from the characterization of three devices for each example. Moreover, the data reported in Table 1 were obtained normalizing, for each example, all the data taking as a reference the power conversion efficiency (PCE) measured just after exposing the device to light soaking, i.e. by exposing the device to the light of a Solartest 1200 (Atlas) solar simulator, able to provide AM 1.5 G radiation with an intensity of 100 mW/cm² (1 sun), for 62 minutes.

TABLE 1

| | | | | PCE⁽³⁾ |
|---|---|---|---|---|
| | | Plasma | T₅₀⁽²⁾ | (%) |
| EXAMPLE | PVP⁽¹⁾ | treatment | (hours) | (after 7000 hours) |
| 1 (invention) | yes | yes | >8000 | 59 |
| 2 (comparative) | no | yes | 7000 | 50 |
| 3 (comparative) | yes | no | 3500 | below threshold |
| 4 (comparative) | no | no | 1700 | below threshold |

⁽¹⁾PVP: poly(-N-vinylpyrrolidone);
⁽²⁾hours of accelarating ageing test at which the power conversion efficiency (PCE) was 50% of the starting value;
⁽³⁾PCE is the power conversion efficiency (PCE) of the device calculated according to the following formula:
$\frac{{V}_{OC} \cdot {J}_{SC} \cdot FF}{{P}_{in}}$

wherein the FF (fill factor) is calculated according to the following formula:

$$\frac{{V}_{MPP} \cdot {J}_{MPP}}{{V}_{OC} \cdot {J}_{SC}}$$

wherein V_{MPP} and J_{MPP} are current tension and current density corresponding to the point of maximum power, respectively, V_{OC} is the open circuit voltage and J_{SC} is short-circuit photocurrent density and Pin is the intensity of the light incident on the device.

The data reported in Table 1 clearly show that the inverted polymer photovoltaic cell (or solar cell) according to the present disclosure is endowed with good power conversion efficiency (PCE) and, in particular, is able to maintain said power conversion efficiency (PCE) stable over time.

1. A process for producing an inverted polymer photovoltaic cell (or solar cell), the process includes the following steps:
providing an electron contact layer (cathode);
depositing a cathodic buffer layer onto said electron contact layer;
depositing a photoactive layer comprising at least one photoactive organic polymer and at least one organic electron acceptor compound onto said cathodic buffer layer;
depositing an anodic buffer layer onto said photoactive layer; and
providing a hole contact layer (anode);
wherein the step of depositing said cathodic buffer layer comprises:
forming a layer onto said electron contact layer of a composition comprising at least one zinc oxide and/or titanium dioxide or a precursor thereof, at least one organic solvent and at least one polymer soluble in said organic solvent; and
plasma treating said layer formed onto said electron contact layer so as to form the cathodic buffer layer.

2. The process for producing an inverted polymer photovoltaic cell (or solar cell) according to claim 1, wherein said electron contact layer (cathode) is made of a material selected from: indium tin oxide (ITO), tin oxide doped with fluorine (FTO), zinc oxide doped with aluminum (AZO), zinc oxide doped with gadolinium oxide (GZO); or it constituted by grids of conductive material, said conductive material being selected from silver (Ag), copper (Cu), graphite, graphene, and by a transparent conductive polymer, said transparent conductive polymer being selected from PEDOT:PSS [poly(3,4-ethylenedioxythiophene):polystyrene sulfonate], polyaniline (PAM); or it is constituted by a metal nanowire-based ink, said metal being selected from silver (Ag) and copper (Cu).

3. The process for producing an inverted polymer photovoltaic cell (or solar cell) according to claim 1, wherein said electron contact layer (cathode) is associated with a support layer that is made of a rigid transparent material such as glass, or flexible material such as polyethylene terephthalate-(PET), polyethylene naphthalate (PEN), polyethyleneimine (PI), polycarbonate (PC), polypropylene (PP), polyimide (PI), triacetyl cellulose (TAC), or their copolymers.

4. The process for producing an inverted polymer photovoltaic cell (or solar cell) according to claim 1, wherein said photoactive organic polymer is selected from:
(a) polythiophenes such as poly(3-hexylthiophene) (P3HT) regioregular, poly(3-octylthiophene), poly(3,4-ethylenedioxythiophene), or mixtures thereof;
(b) conjugated alternating or statistical copolymers comprising:
at least one benzotriazole unit (B) having general formula (Ia) or (Ib): 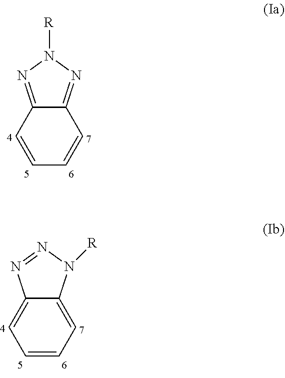
wherein the group R is selected from alkyl groups, aryl groups, acyl groups, thioacyl groups, said alkyl, aryl, acyl and thioacyl groups being optionally substituted;
at least one conjugated structural unit (A), wherein each unit (B) is connected to at least one unit (A) in any of positions 4, 5, 6, or 7;
(c) conjugated alternating copolymers comprising benzothiadiazole units such as PCDTBT {poly[N-9″-heptadecanyl-2,7-carbazole-alt-5,5-(4′, 7′-di-2-thienyl-2′,1′,3′-benzothiadiazole]}, PCPDTBT {poly[2,6-(4,4-bis-(2-ethylhexyl)-4H-cyclopenta [2,1-b; 3,4-b′]-dithiophene)-alt-4,7-(2,1,3-benzotiadiazole)]};
(d) conjugated alternating copolymers comprising thieno[3,4-b]pyrazidine units;
(e) conjugated alternating copolymers comprising quinoxaline units;
(f) conjugated alternating copolymers comprising monomeric silylated units such as copolymers of 9,9-dialkyl-9-silafluorene;
(g) conjugated alternating copolymers comprising condensed thiophene units such as copolymers of thieno[3,4-b] thiophene and of benzo [1,2-b: 4,5-b′] dithiophene;
(h) conjugated alternating copolymers comprising benzothiadiazole or naphtothiadiazole units substituted with at least one fluorine atom and thiophene units substituted with at least one fluorine atom such as PffBT4T-2OD {poly[(5,6-difluoro-2,1,3-benzothiadiazol-4,7-diyl)-alt-(3,3′″-(2-octyldodecyl)-2,2′,5′,2″;5″,2″-quaterthiophene-5,5″-diil)]}, PBTff4T-2OD {poly[(2,1,3-benzothiadiazole-4,7-diyl)-alt-(4′,3″-difluoro-3,3″′-(2-octyldodecyl)-2,2′;5′,2″;5″,2″-quaterthiophene-5,5″-diyl)]}, PNT4T-2OD {poly(naphtho[1,2-c:5,-c′]bis [1,2,5] thiadiazole-5,10-diyl)-alt-(3,3′″-(2-octyldodecyl)-2,2′; 5′,2″; 5″,2″-quaterthiophene-5,5′″-diyl)];
(i) conjugated copolymers comprising thieno[3,4-c]pyrrole-4,6-dione units such as PBDTTPD {poly[[5-(2-ethylhexyl)-5,6-dihydro-4,6-dioxo-4H-thieno[3,4-c]pyrrole-1,3-diyl][4,8-bis[(2-ethylhexyl)oxy]benzo-[1,2-b:4,5-b′] dithiophene-2,6-diyl]};
(l) conjugated copolymers comprising thienothiophene units such as PTB7 {poly({4,8-bis[(2-ethylhexyl)oxy]benzo[1,2-b:4,5-b′]dithiophene-2,6-diyl}{3-fluoro-2-[(2-ethylhexyl)carbonyl]thieno [3,4-b]thiophenediyl}};
(m) polymers comprising a derivative of indacen-4-one having general formula (III), (IV) or (V): 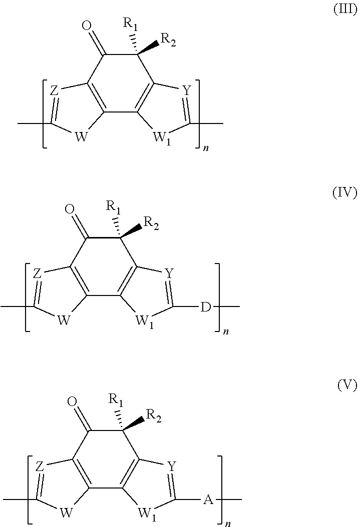
wherein:
W and W₁, identical or different, represent an oxygen atom; a sulfur atom; an N—R₃ group wherein R₃ represents a hydrogen atom, or is selected from linear or branched C₁-C₂₀ alkyl groups;
Z and Y, identical or different, represent a nitrogen atom; or a C—R₄ group wherein R₄ represents a hydrogen atom, or is selected from linear or branched C₁-C₂₀ alkyl groups, optionally substituted cycloalkyl groups, optionally substituted aryl groups, optionally substituted heteroaryl groups, linear or branched C₁-C₂₀ alkoxy groups, R₅—O—[CH₂—CH₂—O]ₙ— polyethylenoxyl groups wherein R₅ is selected from linear or branched C₁-C₂₀ alkyl groups, and n is an integer ranging from 1 to 4, —R₆—OR₇ groups wherein R₆ is selected from linear or branched C₁-C₂₀ alkyl groups, and R₇ represents a hydrogen atom or is selected from linear or branched C₁-C₂₀ alkyl groups, or is selected from R₅—[—OCH₂—CH₂—]ₙ— polyethylenoxyl groups wherein R₅ has the same meanings reported above and n is an integer ranging from 1 to 4, —COR₈ groups wherein R₈ is selected from linear or branched C₁-C₂₀ alkyl groups; —COOR₉ groups wherein R₉ is selected from linear or branched C₁-C₂₀ alkyl groups; or represent a —CHO group, or a cyano group (—CN);
R₁ and R₂, identical or different, preferably identical, are selected from linear or branched C₁-C₂₀ alkyl groups; optionally substituted cycloalkyl groups; optionally substituted aryl groups; optionally substituted heteroaryl groups; linear or branched C₁-C₂₀ alkoxy groups; R₅—O—[CH₂—CH₂—O]ₙ— polyethylenoxyl groups wherein R₅ has the same meanings reported above and n is an integer ranging from 1 to 4; —R₆—OR₇ groups wherein R₆ and R₇ have the same meanings reported above; —COR₈ groups wherein R₈ has the same meanings as above; or —COOR₉ groups wherein R₉ has the same meanings as above; or represent a —CHO group, or a cyano group (—CN);
D represents an electron-donor group;
A represents an electron acceptor group;
n is an integer ranging from 10 to 500;
or mixtures thereof.

5. The process for producing an inverted polymer photovoltaic cell (or solar cell) according to claim 4, wherein said photoactive organic polymer is selected from: PffBT4T-2OD {poly[(5,6-difluoro-2,1,3-benzothiadiazol-4,7-diyl)-alt-(3,3′″-(2-octyl-dodecyl)-2,2′,5′,2″;5″,2″-quaterthiophene-5,5″-diyl)]}, PBDTTPD {{poly[[5-(2-ethylhexyl)-5,6-dihydro-4,6-dioxo-4H-thieno[3,4-c]pyrrole-1,3-diyl][4,8-bis[(2-ethylhexyl)oxy]benzo[1,2-b:4,5-b′]dithiophene-2,6-diyl]}, PTB7{poly({4,8-bis[(2-ethylhexyl)oxo]benzo[1,2-b:4,5-b′]dithiophene-2,6-diyl}{3-fluoro-2-[(2-ethylhexyll)carbonyl]thieno[3,4-b]thiophenediyl})}, or mixtures thereof.

6. The process for producing an inverted polymer photovoltaic cell (or solar cell) according to claim 1, wherein said organic electron acceptor compound is selected from fullerene derivatives such as [6,6]-phenyl-C₆₁-butyric acid methyl ester (PC₆₁BM), [6,6]-phenyl-C₇₁-butyric acid methyl ester (PC₇₁BM), bis-adduct indene-C₆₀ (ICBA), bis(1-[3-(methoxycarbonyl)propyl]-1-phenyl)-[6,6]C₆₂ (Bis-PCBM), or mixtures thereof.

7. The process for producing an inverted polymer photovoltaic cell (or solar cell) according to claim 1, wherein said of the present invention, said organic electron acceptor compound is selected from non-fullerene, optionally polymeric, compounds such as compounds based on perylene-diimides or naphthalene-diimides and fused aromatic rings; indacenothiophene with terminal electron-poor groups; compounds having an aromatic core able to symmetrically rotate such as derivatives of corannulene or truxenone; or mixtures thereof; selected from 3,9-bis{2-methylene-[3-(1,1-dicyanomethylene)-indanone]}-5,5,11,11-tetrakis(4-hexylphenyl)-dithieno[2,3-d:2′,3′-d′]-s-indaceno[1,2-b: 5,6-b′]dithiophene, poly {[N,N′-bis (2-octyldodecyl)-1,4,5,8-naftalenediimide-2,6-diyl]-alt-5,5′-(2,2′-bithiophene)}.

8. The process for producing an inverted polymer photovoltaic cell (or solar cell) according to claim 1, wherein said anodic buffer layer is selected from PEDOT:PSS [poly(3,4-ethylenedioxythiophene):polystyrene sulfonate], polyaniline (PANI).

9. The process for producing an inverted polymer photovoltaic cell (or solar cell) according to claim 1, wherein said anodic buffer layer is selected from hole transporting material obtained through a process comprising: (a) reacting at least one heteropoly acid containing at least one transition metal belonging to group 5 or 6 of the Periodic Table of the Elements such as phosphomolybdic acid hydrate {H₃[P(MoO₃)₁₂O₄].nH₂O}, phosphomolybdic acid {H₃[P(MoO₃)₁₂O₄]} in alcoholic solution, silicotungstic acid hydrate {H₄[Si(WO₃)₁₂O₄].nH₂O}, or mixtures thereof; with (b) an equivalent amount of at least one salt or one complex of a transition metal belonging to group 5 or 6 of the Periodic Table of the Elements with an organic anion, or with an organic ligand such as molybdenum(VI) dioxide bis(acetylacetonate) (Cas No. 17524-05-9), vanadium(V) oxytriisopropoxide (Cas No. 5588-84-1), bis (acetylacetonate) oxovanadium (IV) (Cas No. 3153-26-2), or mixtures thereof in the presence of at least one organic solvent selected from alcohols, ketones, esters.

10. The process for producing an inverted polymer photovoltaic cell (or solar cell) according to claim 1, wherein said hole contact layer (anode) is made of metal, said metal being preferably selected from silver (Ag), gold (Au), and aluminum (Al); or it is constituted by grids of conductive material, said conductive material being preferably selected from silver (Ag), copper (Cu), graphite, graphene, and by a transparent conductive polymer, said transparent conductive polymer being preferably selected from PEDOT:PSS [poly(3,4-ethylenedioxythiophene):polystyrene sulfonate], polyaniline (PAM); or it is constituted by a metal nanowire-based ink, said metal being selected from silver (Ag) and copper (Cu).

11. The process for producing an inverted polymer photovoltaic cell (or solar cell) according to claim 1, wherein said zinc oxide precursor is selected from zinc salts and zinc complexes such as: zinc acetate, zinc formiate, zinc acetylacetonate, zinc alcoholates (such as methoxide, ethoxide, propoxide, iso-propoxide, butoxide), zinc carbamate, zinc bis(alkylamide(s), zinc dialkyls or diaryls (such as diethylzinc, diphenylzinc), or mixtures thereof.

12. The process for producing an inverted polymer photovoltaic cell (or solar cell) according to claim 1, wherein said titanium oxide precursor is selected from titanium salts and titanium complexes such as: titanium acetate, titanium formiate, titanium acetylacetonate, titanium alcoholates (such as methoxide, ethoxide, propoxide, iso-propoxide, butoxide), titanium carbamate, titanium bis(alkylamide(s), titanium dialkyls or diaryls (such as diethyltitanium, diphenyltitanium), or mixtures thereof.

13. The process for producing an inverted polymer photovoltaic cell (or solar cell) according to claim 1, wherein said at least one zinc oxide is in the form of colloidal nanoparticles; colloidal zinc oxide nanoparticles have an average particle size ranging from 5 nm to 50 nm.

14. The process for producing an inverted polymer photovoltaic cell (or solar cell) according to claim 1, wherein the amount of said zinc oxide and/or titanium dioxide or precursor thereof, in said composition is ranging from 1% by weight to 30% by weight, with respect to the total weight of the composition.

15. The process for producing an inverted polymer photovoltaic cell (or solar cell) according to claim 1, wherein said at least one organic solvent is selected from: alcohols such as methanol, ethanol, propanol, iso-propanol, butanol, or mixtures thereof; aromatic solvents such as toluene, o-xylene, m-xylene, p-xylene, or mixture thereof; aliphatic solvents such as hexane, heptane, or mixtures thereof; heteroaromatic solvents such as tetrahydrofuran, or mixtures thereof; heterocyclic solvents such as dioxane, or mixtures thereof; oxygenated solvents such as diethyl ether, dimethoxyethane, or mixtures thereof; polar solvents such as acetonitrile, N,N-dimethylformamide, N,N-dimethylacetamide, or mixtures thereof.

16. The process for producing an inverted polymer photovoltaic cell (or solar cell) according to claim 1, wherein said at least one polymer soluble in said organic solvent is selected from: poly(vinyllactames) such as poly(N-vinylpyrrolidone) (PVP), poly(N-vinylcaprolactam), poly(N-vinylbutirolactam), or mixtures thereof; poly(N-acylimines such as poly(N-acetylimine), poly(N-propanoylimine), or mixtures thereof; N,N-dialkyl substituted poly(acrylamides) such as poly(N,N-dimethylacrylamide), poly(N,N-diethylacrylamide), or mixtures thereof; poly[hydroxyalkyl(meth)acrylates such as poly(2-hydroxethylmethacrylate), or mixtures thereof; poly(vinylpyridines) such as poly(2-vinylpiridine), poly(-vinylpiridine), or mixtures thereof; poly(alkylglycols) such as poly(ethyleneglycol), poly(propyleneglycol), or mixtures thereof; or mixtures thereof; the amount of said polymer, in the composition being ranging from 0.02% by weight to 10% by weight, with respect to the total weight of the composition.

17. The process for producing an inverted polymer photovoltaic cell (or solar cell) according to claim 1, wherein said plasma treating is carried out:
in the presence of an inorganic gas such as argon (Ar), helium (He), nitrogen (N₂), oxygen (O₂), or mixtures thereof; and/or
under a discharge power ranging from 10 W to 1000 W.

18. The process for producing an inverted polymer photovoltaic cell (or solar cell) according to claim 1, wherein in said inverted polymer photovoltaic cell (or solar cell):
the electron contact layer (cathode) has a thickness ranging from 50 nm to150 nm;
the cathodic buffer layer has a thickness ranging from 10 nm to 100 nm;
the photoactive layer has a thickness ranging from 50 nm to 250 nm;
the anodic buffer layer has a thickness ranging from 200 nm to 2000 nm; and
the hole contact layer (anode) has
a thickness ranging from 5000 nm to 15000 nm, preferably ranging from 8000 nm to 12000 nm.
